(19) United States
(12) Patent Application Publication
(10) Pub. No.: US 2013/0242471 A1
(43) Pub. Date: Sep. 19, 2013

(54) FORWARD LID-LIFT DEVICE AND ELECTRONIC APPARATUS HAVING THE SAME

(71) Applicants: TSUNG-CHI HUNG, New Taipei City (TW); CHAO-CHU WU, New Taipei City (TW)

(72) Inventors: TSUNG-CHI HUNG, New Taipei City (TW); CHAO-CHU WU, New Taipei City (TW)

(73) Assignee: UNIFORM INDUSTRIAL CORP.

(21) Appl. No.: 13/547,273

(22) Filed: Jul. 12, 2012

(30) Foreign Application Priority Data
Mar. 14, 2012 (TW) 101204635

(51) Int. Cl. H05K 7/00

(52) U.S. Cl. 361/679.01; 49/358

(57) ABSTRACT

A forward lid-lift device assembled to a counteraction member of an electronic apparatus includes a main lid and a turning lid. The main lid includes a first rotary shaft connected with the counteraction member, and an engaging end fastened at the end of the electronic apparatus opposite to the first rotary shaft. The turning lid includes a second rotary shaft connected to the main lid, a poking end at an end of the second rotary shaft, and a pushing member at the other end of the second rotary shaft. When the pushing member rotates from a start point to an end point along a second turning path in a first direction, the interference between a first turning path of the counteraction member and the second turning path is increased gradually and the main lid and the turning lid are both turned in the same direction to complete lid-lift action.

### CROSS-REFERENCES TO RELATED APPLICATIONS

This non-provisional application claims priority under 35 U.S.C. §119(a) on Patent Application No. 101204635 filed in Taiwan, R.O.C. on 2012 Mar. 14, the entire contents of which are hereby incorporated by reference.

### BACKGROUND

1. Technical Field

The disclosure relates to a lid-lift device, and in particular to a forward lid-lift device with a turning lid to lift a main lid in an equal direction.

2. Related Art

Currently, point of sales (POS) devices such as electronic data capture (EDC) system and card readers are commonly used in retailers to accept plastic money from customers; for example, expense cards, credit cards and debit cards. Such electronic payment can quickly and easily complete transactions and provide requested services for the customers. With the advent of prepaid cards and other smart cards, the number of POS devices used for various purposes will increase substantially in the next few years.

POS devices such as thermal receipt printers, which use paper rolls to print data, are widely used. In particular, the thermal receipt printers need easily loaded and replaced paper rolls. For the convenience of replacing paper rolls, the POS device must have a lid-lift cover structure. However, the lid-lift cover structure is commonly designed for a reversed opening action. The lid-lift cover structure has a cover and a turning member arranged thereon, and the lifting direction of the cover is different from that of the turning member. Thus, users need to lift the cover in an opposite direction after lifting the turning member, causing inconvenience of operation. Consequently, manufacturers in this industry are committed to explore this issue.

### SUMMARY

Accordingly, in an embodiment of the disclosure, a forward lid-lift device is provided to assemble to a counteraction member of an electronic apparatus. The counteraction member has a first turning path. The forward lid-lift device includes a main lid and a turning lid. The main lid includes a first rotary shaft and an engaging end. The first rotary shaft connects to the counteraction member. The engaging end is fastened at the end of the electronic apparatus opposite to the first rotary shaft. The turning lid includes a second rotary shaft, a poking end and a pushing member. The second rotary shaft connects to the main lid. The poking end is at a side by the second rotary shaft. The pushing member is at the other side by the second rotary shaft. The pushing member has a second turning path. When the pushing member rotates from a start point to an end point along the second turning path, the interference between the first turning path and the second turning path is increased gradually, meanwhile the main lid and the turning lid will turn in the same direction to complete lid-lift action.

In another embodiment, an electronic apparatus is also provided to allow the forward lid-lift device to assemble thereon. The electronic apparatus includes a shell body and the counteraction member. The shell body connects the first rotary shaft of the main lid. The counteraction member is disposed on the shell body to contact with the pushing member. The counteraction member has the first turning path which is shorter than the second turning path corresponding to the pushing member. When the pushing member rotates from a start point to an end point along the second turning path, the interference between the second turning path and the first turning path corresponding to the counteraction member is increased gradually, meanwhile when the pushing member turns in a first direction, the main lid and the turning lid will both turn in a second direction to complete lid-lift action.

A lid-lift action is completed once by the main lid and the turning lid of the forward lid-lift device, so users may operate it easily. Meanwhile, the turning lid and the pushed counteraction member have a different rotation center and different turning path, respectively. A force applied by users increases gradually until the lid-lift action is over, so users can apply the force smoothly.

### BRIEF DESCRIPTION OF THE DRAWINGS

The disclosure will become more fully understood from the detailed description given herein below for illustration only, and thus not limitative of the disclosure, wherein:

FIG. 1 is a stereoscopic schematic diagram according to an embodiment;

FIG. 2 is an exploded schematic diagram according to another embodiment;

FIG. 3 is the other exploded schematic diagram according to another embodiment;

FIG. 4 is a stereoscopic schematic diagram when lifting the lid according to another embodiment;

FIG. 5 is a cross-section schematic diagram when lifting the lid according to another embodiment;

FIG. 6 is a cross-section schematic diagram after lifting the lid according to another embodiment; and

FIG. 7 is a stereoscopic schematic diagram after lifting the lid according to another embodiment.

### DETAILED DESCRIPTION

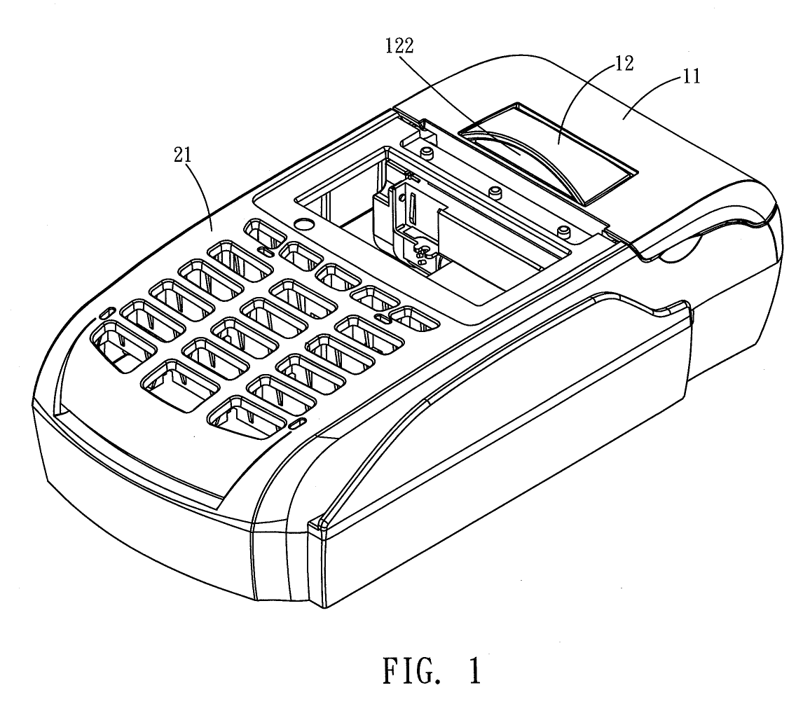

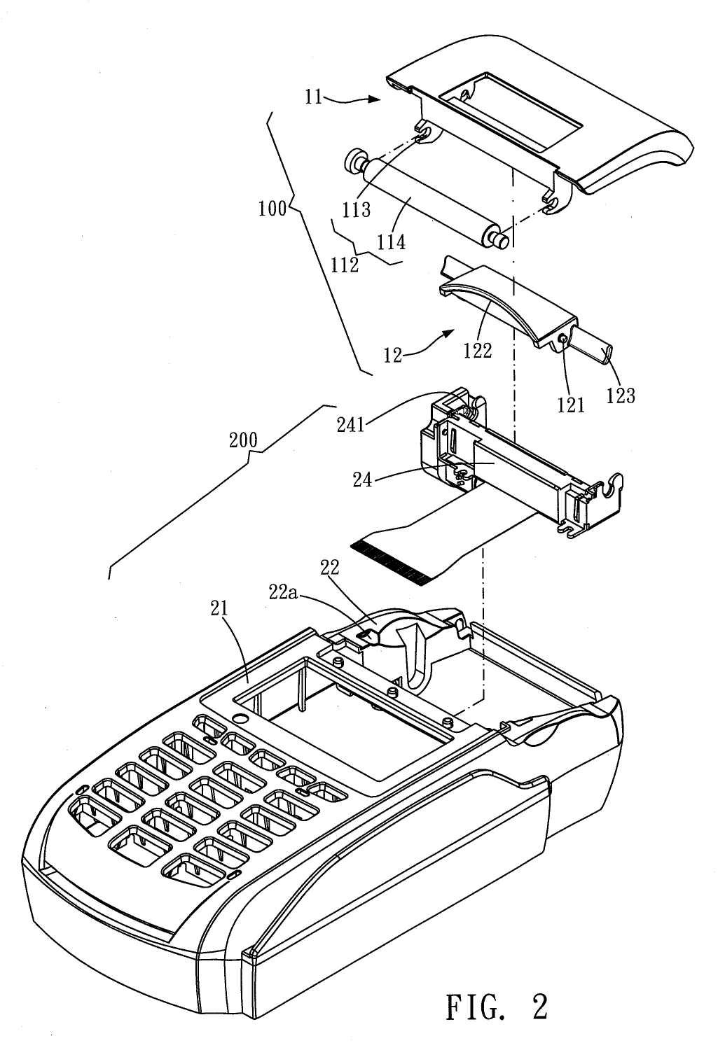

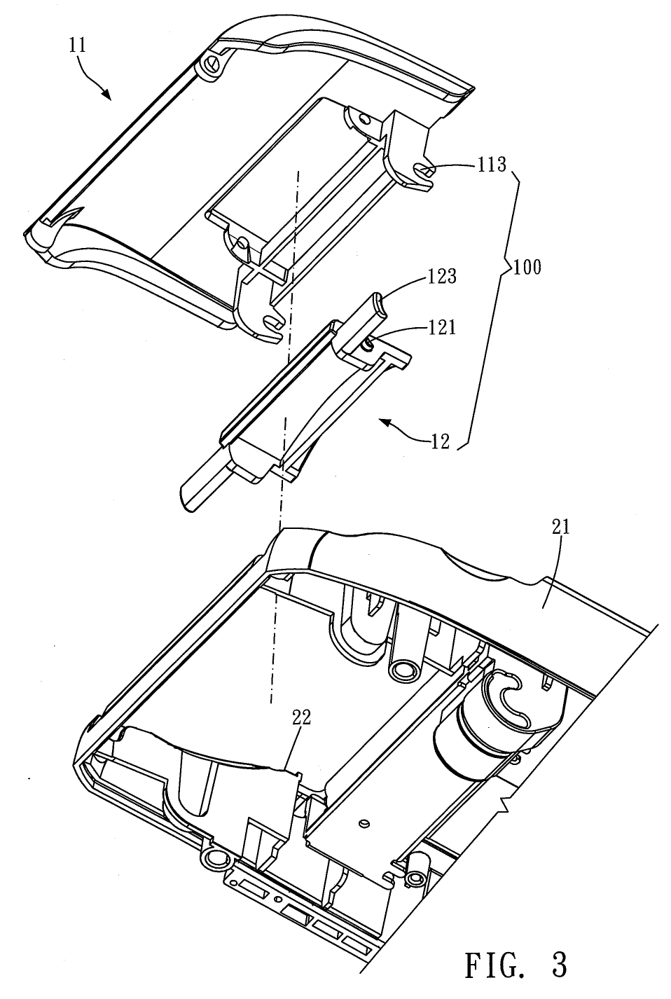

Please refer to FIGS. 1, 2 and 3. FIG. 1 is a stereoscopic schematic diagram according to an embodiment. FIG. 2 is an exploded schematic diagram according to another embodiment. FIG. 3 is the other exploded schematic diagram according to another embodiment.

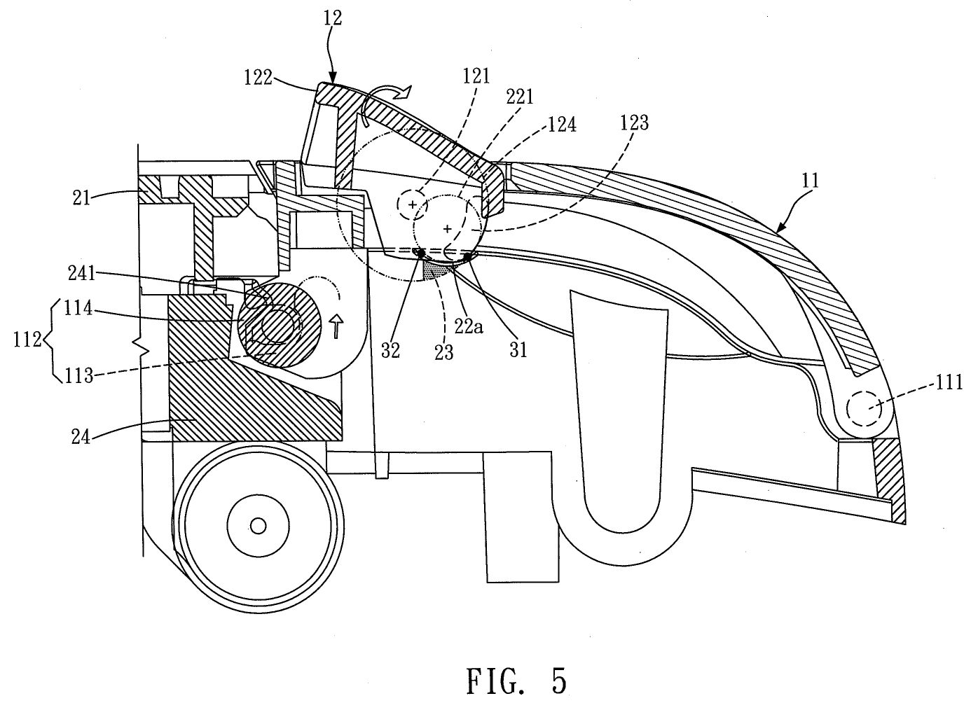

A forward lid-lift device 100 in the figures of the disclosure is assembled to a counteraction member 22 of an electronic apparatus 200. The counteraction member 22 preferably is as an upper shell of the electronic apparatus 200, as shown in FIG. 1. The counteraction member 22 has a first turning path 221 (as shown in FIG. 5). The counteraction member 22 includes a recess 22a to form the first turning path 221. The forward lid-lift device 100 includes a main lid 11 and a turning lid 12.

The main lid 11 is an arc-shaped plate and has a first rotary shaft at an end of the main lid 11 to connect with the counteraction member 22 of the electronic apparatus 200, for example, using a shaft with a hole. The main lid 11 further has an engaging end 112 at the other end of the main lid 11. The engaging end 112 is fastened at the end of the electronic apparatus 200 opposite to the first rotary shaft 111. The engaging end 112 includes a catching groove 113 and a rod 114.

The turning lid 12 is a poking element and includes a second rotary shaft 121, a poking end 122 and a pushing member 123. The second rotary shaft 121 connects to the main lid 11 to allow the turning lid 12 to turn circularly according to the second rotary shaft 121 as a center. The poking end 122 is at a side by the second rotary shaft 121 and exposed to the main lid 11 to facilitate poking operation by the user's finger thereon. The pushing member 123 is arranged at the other side by the second rotary shaft 121 and formed as an arc-shaped bump. The pushing member 123 has a second turning path 124 and rotates according to the second rotary shaft 121 as a center. When the pushing member 123 rotates from a start point 31 to an end point 32 (as shown in FIG. 5), along the second turning path 124, the interference between the first turning path 221 and the second turning path 124 is increased gradually. Here, the radius of the first turning path 221 is smaller than the radius of the second turning path 124, and the position of the center of the first turning path 221 is different from that of the second turning path 124. Meanwhile, the first turning path 221 is tangent to the second turning path 124 and overlaps the second turning path 124 to form an interacting section 23 which is a gradual expansion area from small to large. Consequently, a force applied by users while turning the turning lid 12, increases gradually to complete a lid-lift action, so users can apply the force smoothly.

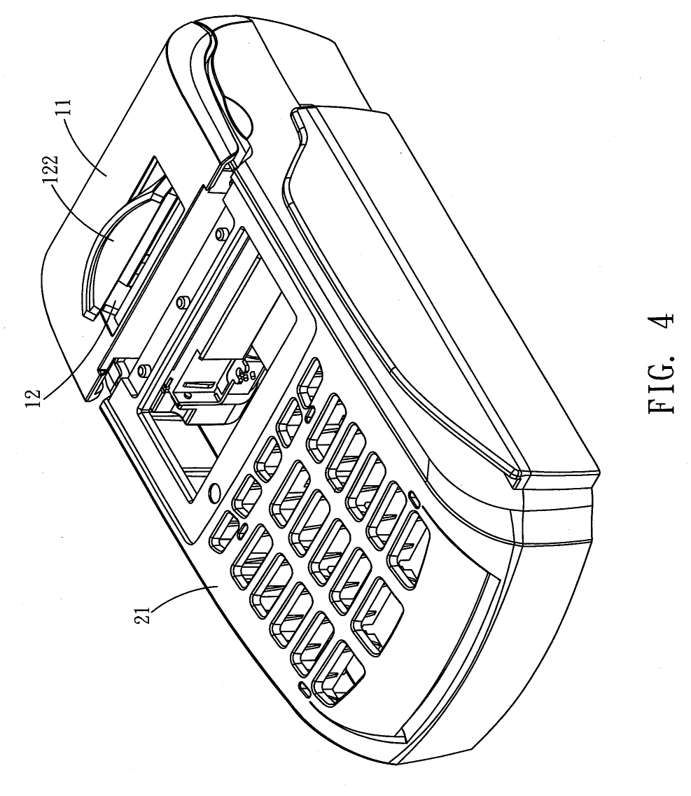

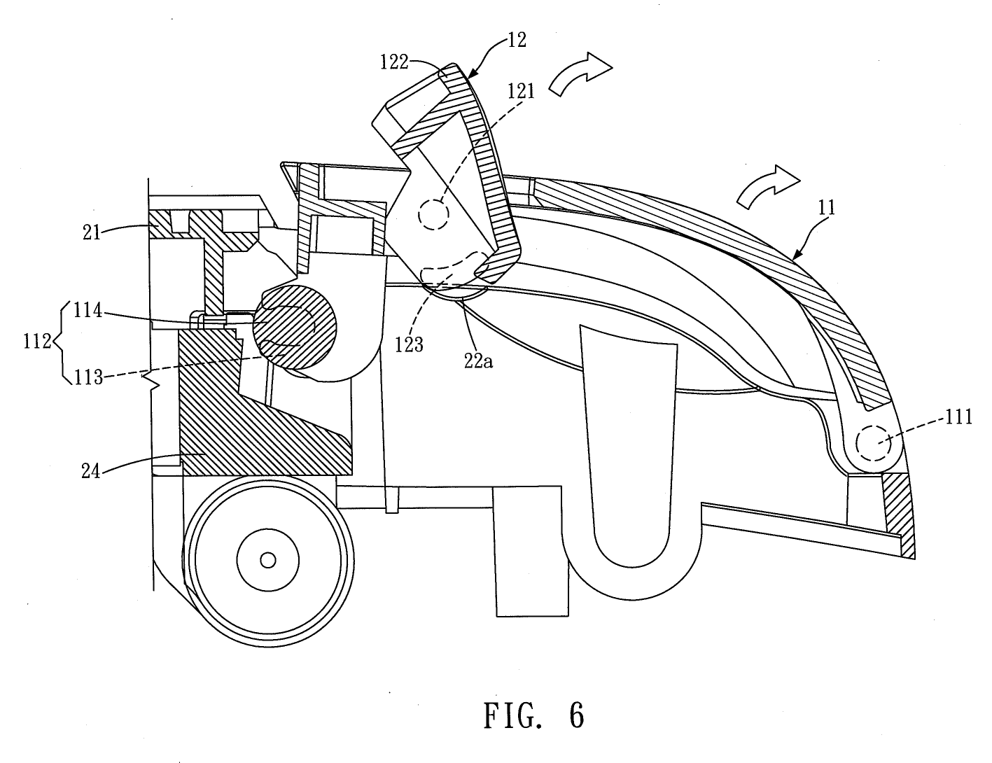

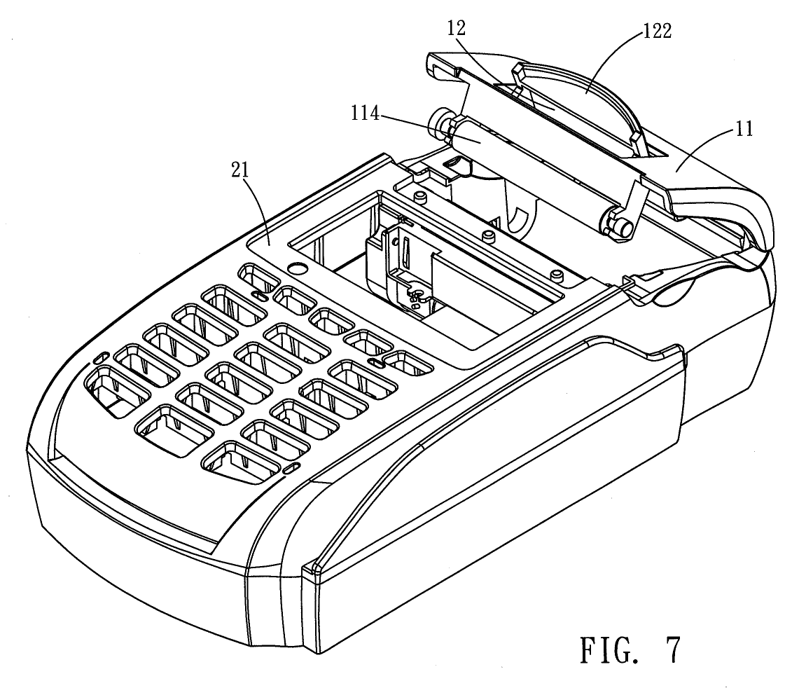

Please refer to FIGS. 4, 5, 6 and 7. When the turning lid 12 is turned, the pushing member 124 of the turning lid 12 rotates in a first direction (e.g., counterclockwise direction), and the main lid 11 and the turning lid 12 turn in a second direction (e.g., clockwise direction), so that the lid-lift action is completed in a one-time and continuous manner after lifting up the lid. The lifting method provided by the forward lid-lift device 100 not only saves effort, but also has user-friendly advantages of being effortless and easy to use.

Please refer to FIGS. 1 and 2. Here, the electronic apparatus 200 may be a card reader for credit cards, access cards, etc., but is not limit to. The electronic apparatus 200 may include any type of input elements (e.g., buttons), a reading element, a display element (e.g., a screen), a printing element or a paper roll (not shown in figures). The electronic apparatus 200 includes a shell body 21 and a counteraction member 22.

The shell body 21 is preferably formed by a upper shell and a lower shell. A part of the shell body 21 is a hollow section. The hollow section on the upper shell is where the counteraction member 22 is disposed. The shell body 21 connects to the first rotary shaft 111 of the main lid 11.

The counteraction member 22 is disposed on the two sidewalls of the shell body 21. The counteraction member 22 may has a cambered surface or a recess 22a. The counteraction member 22 contacts with the pushing member 123 and has the first turning path 221 shorter than the second turning path 124 of the pushing member 123 as aforementioned. The operation between the counteraction member and the rotated pushing member 123 has mentioned previously, and we do not describe it further herein. Therefore, after lifting up the lid, the paper roll placed inside the shell body 21 can be taken out.

In an embodiment, the electronic apparatus 200 further includes a connection module 24 disposed on the shell body 21. The connection module 24 includes a holding portion 241. The holding portion 241 is preferably as a locking groove type, and has an elastic locking stick.

When the rod 114 at the engaging end 112 of the main lid 11 is put into the holding portion 241, the rod 114 will be locked by the elastic locking stick to be fixed in the locking groove.

In the disclosure, the turning lid and the main lid of the forward lid-lift device can be lifted in the same direction to complete the lid-lift action one time continuously, so that users can operate it easily. Meanwhile, the turning lid and the pushed counteraction member have different rotation center and different turning path, respectively. A force applied by users increases gradually until the lid-lift action is over, so users can apply the force smoothly.

While the present invention has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A forward lid-lift device, assembled to a counteraction member of an electronic apparatus having a first rotary shaft, comprising:
a main lid, pivotally connecting to the counteraction member at an end of the main lid, and fastened to the electronic apparatus at the other end of the main lid; and
a turning lid, pivotally connecting to the main lid at an end of the turning lid, and comprising:
a poking end; and
a pushing member, arranged at an end opposite to the poking end and having a second turning path, wherein when the pushing member rotates from a start point to an end point along the second turning path in a first direction, the interference between the first turning path and the second turning path is increased gradually and the main lid and the turning lid are both turned in a second direction to complete lid-lift action.

2. The forward lid-lift device according to claim 1, wherein the main lid comprises a first rotary shaft at an end of the main lid to pivotally connect to the counteraction member.

3. The forward lid-lift device according to claim 1, wherein the main lid comprises an engaging end at the other end of the main lid to be fastened to the electronic apparatus.

4. The forward lid-lift device according to claim 1, wherein the engaging end comprises a catching groove to connect with a rod.

5. The forward lid-lift device according to claim 1, wherein the turning lid further comprises a second rotary shaft to connect with the main lid.

6. An electronic apparatus, comprising:
the forward lid-lift device according to any one of claim 1;
a shell body, connected to the main lid; and
a counteraction member, disposed on the shell body to contact with the pushing member, and having the first turning path shorter than the second turning path corresponding to the pushing member, wherein when the pushing member rotates from a start point to an end point along the second turning path in a first direction, the interference between the first turning path and the second turning path corresponding to the counteraction member is increased gradually and the main lid and the turning lid are both turned in a second direction to complete lid-lift action.

7. The electronic apparatus according to claim 6, wherein the center of the first turning path corresponding to the counteraction member is different from the center of the second turning path corresponding to the pushing member.

8. The electronic apparatus according to claim 6, wherein the counteraction member comprises a recess to form the first turning path to accept the pushing member.

9. The electronic apparatus according to claim 6 further comprising a connection module arranged on the shell body, wherein the connection module comprises a holding portion.

10. The electronic apparatus according to claim 6, wherein the main lid comprises a first rotary shaft at an end of the main lid to pivotally connect to the counteraction member.

11. The electronic apparatus according to claim 6, wherein the main lid comprises an engaging end at the other end of the main lid to be fastened to the electronic apparatus.

12. The electronic apparatus according to claim 6, wherein the engaging end comprises a catching groove to connect with a rod.

13. The electronic apparatus according to claim 6, wherein the turning lid further comprises a second rotary shaft to connect with the main lid.
